(19) United States
(12) Patent Application Publication
(10) Pub. No.: US 2009/0178703 A1
(43) Pub. Date: Jul. 16, 2009

(54) Configurable Articulated Photovoltaic Assembly

(76) Inventor: Michael L. Gumm, Santa Cruz, CA (US)

Correspondence Address: PATWRITE LLC, 408 W. MAIN ST., MARSHALLTOWN, IA, 50158-5759, US

(21) Appl. No.: 12/352,605

(22) Filed: Jan. 12, 2009

Related U.S. Application Data
(60) Provisional application No. 61/010,464, filed on Jan. 10, 2008.

(51) Int. Cl. H01L 31/042

(52) U.S. Cl. 136/244

(57) ABSTRACT

A configurable articulated photovoltaic assembly comprises a plurality of photovoltaic modules hingedly connected to each other to allow the assembly to fold flat for storage and transportation. In one embodiment, a plurality of base attachment plates are also joined with a riser to provide an assembly that can be articulated and placed at a selected angle to optimize their efficiency. This embodiment forms a triangular assembly in use. In another embodiment, two risers are used to provide a selectable channel that can also be folded flat when not in use. Hinges are bidirectional and include metal, fabric and sliding extension types. Each module is wired and connected to a junction box attached therein.

### RELATED APPLICATIONS

This application claims priority and herein incorporates by reference U.S. provisional patent application 61/010,464 filed Jan. 10, 2008.

### BACKGROUND OF THE INVENTION

The present invention is a new multiple configurable articulating photovoltaic assembly and installation method(s) created by combining photovoltaic modules together, connecting individual photovoltaic panel units together with any type of folding, movable, swinging or flexible articulated joint(s) for both horizontal and vertical placement on a building surface or construction substrate.

In one configuration, the rigid photovoltaic solar enabled panels can be combined with other non-solar rigid panel components using any type articulating joint(s) composed of either flexible membranes, textiles or pivoting, swinging, sliding hinges to form a self-contained foldable photovoltaic module array for ease of product assemble, shipping and installation and can be applied to a building surface once configured into any number geometrical forms. The assembled invention, folded for ease of packaging and shipping is shipped to the project site where the solar module array can be unfolded into different construction configurations and installed over a broad range of building and construction surfaces, including roofs, metal, walls and concrete.

### SUMMARY OF THE INVENTION

A configurable articulated photovoltaic assembly comprises a plurality of photovoltaic modules hingedly connected to each other to allow the assembly to fold flat for storage and transportation. In one embodiment, a plurality of base attachment plates are also joined with a riser to provide an assembly that can be articulated and placed at a selected angle to optimize their efficiency. This embodiment forms a triangular assembly in use. In another embodiment, two risers are used to provide a selectable channel that can also be folded flat when not in use. Hinges are bidirectional and include metal, fabric and sliding extension types. Each module is wired and connected to a junction box attached therein.

Other features and advantages of the instant invention will become apparent from the following description of the invention which refers to the accompanying drawings.

### BRIEF DESCRIPTION OF THE DRAWINGS

FIG. 1 is a perspective drawing of a configurable articulated photovoltaic assembly according to an embodiment of the invention.

FIG. 2 is a perspective drawing of the configurable articulated photovoltaic assembly shown in FIG. 1.

FIG. 3 is a perspective drawing of the configurable articulated photovoltaic assembly shown in FIG. 1.

FIG. 4 is a perspective drawing of the configurable articulated photovoltaic assembly shown in FIG. 1.

FIG. 5 is a side view of the configurable articulated photovoltaic assembly shown in FIG. 1.

FIG. 6 is a close up of the section shown in FIG. 5.

FIG. 7 is a side view of the configurable articulated photovoltaic assembly shown in FIG. 1 in a folded position.

FIG. 8 is a perspective drawing of a configurable articulated photovoltaic assembly according to an embodiment of the invention.

FIG. 9 is a side view of the configurable articulated photovoltaic assembly shown in FIG. 8 in a folded position.

FIG. 10 is a perspective drawing of the configurable articulated photovoltaic assembly shown in FIG. 9.

FIG. 11 is a perspective drawing of a configurable articulated photovoltaic assembly according to an embodiment of the invention.

### DETAILED DESCRIPTION OF THE INVENTION

In the following detailed description of the invention, reference is made to the drawings in which reference numerals refer to like elements, and which are intended to show by way of illustration specific embodiments in which the invention may be practiced. It is understood that other embodiments may be utilized and that structural changes may be made without departing from the scope and spirit of the invention.

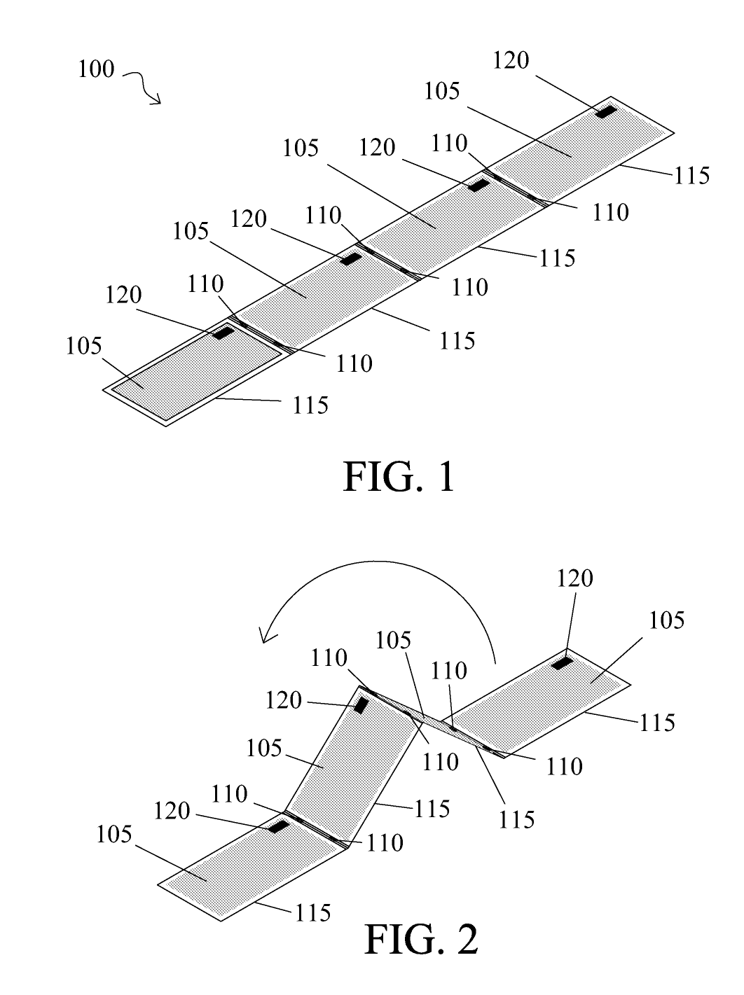

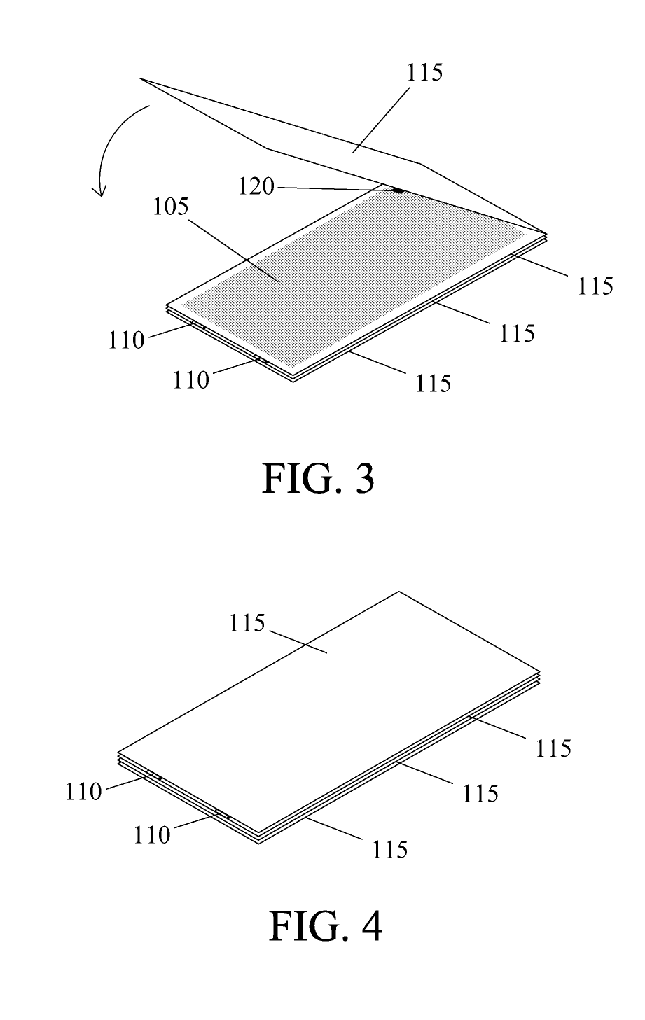

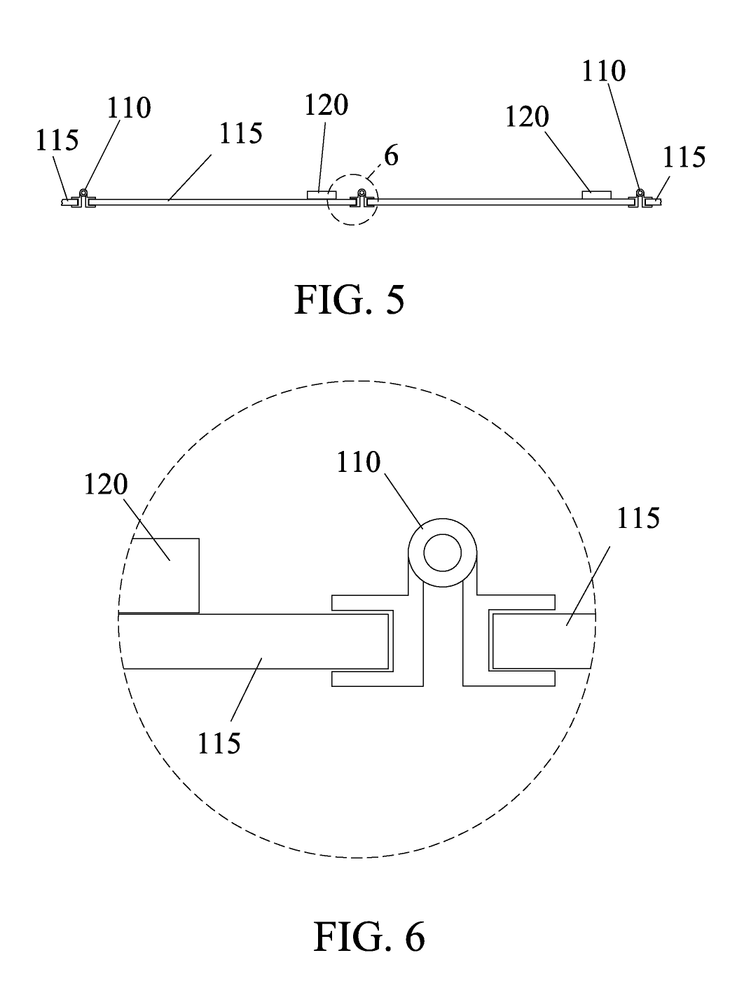

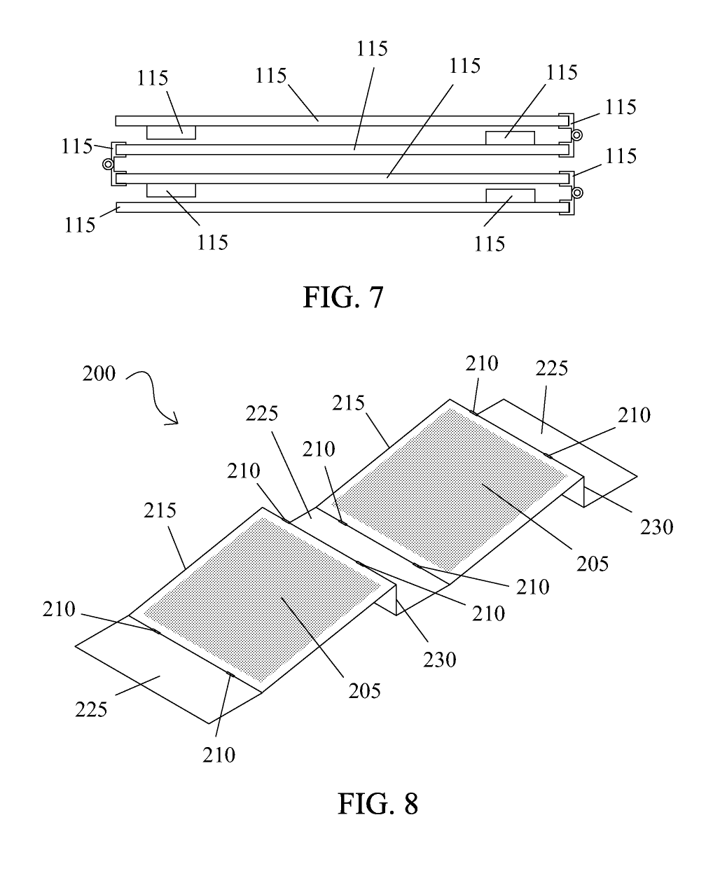

Referring to FIGS. 1 through 7, a configurable articulated photovoltaic assembly 100 comprises a plurality of photovoltaic modules 105 being attached to a support substrate 115 which can be made of glass or non glass materials including metal, polymers, composites, etc. that add to the structural integrity of the modules 105. A plurality of hinge members 110 join each module 105 allowing articulation. A plurality of junction boxes 120 are used to provide electrical communication and control of each module 105. Hinge members 110 allow modules 105 to fold relatively flat for ease in transportation and storage when not in use.

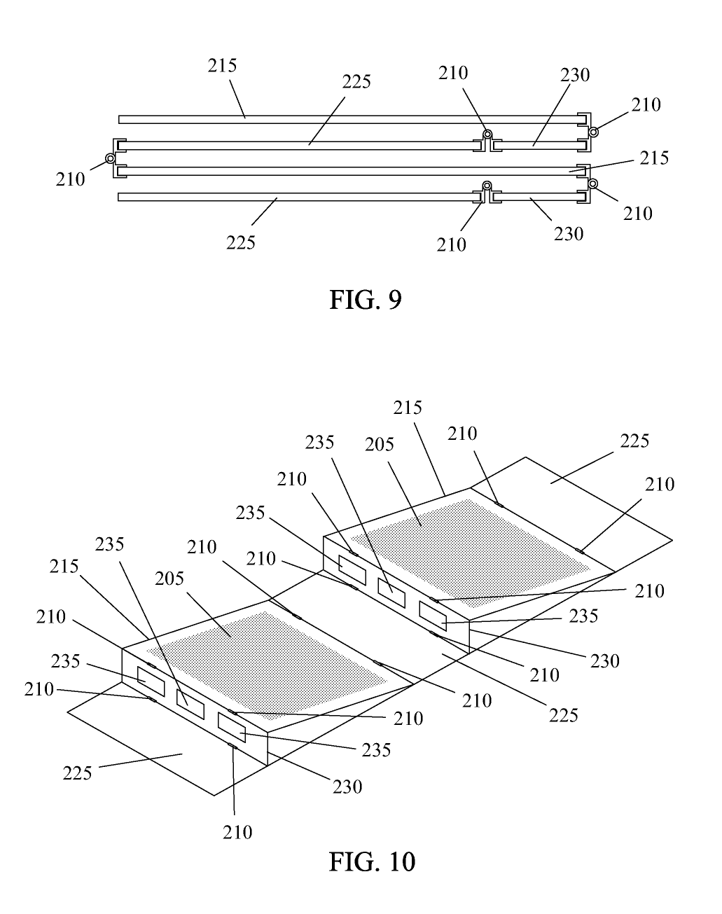

Now referring to FIGS. 8 and 9, a configurable articulated photovoltaic assembly 200 comprises a plurality of photovoltaic modules 205 being attached to a support substrate 215 which as discussed above, can be made of glass or non glass materials including metal, polymers, composites, etc. that add to the structural integrity of the modules 205.

A plurality of base attachment plates 225 are attached to one end of modules 205. A plurality of risers 230 are hingedly attached to one end of module 205 and to an end of base attachment plates 225. This allows configurable articulated photovoltaic assembly 200 to fold generally flat when not in use and to be positioned at a selected angle (90 degrees in figures) to optimize their efficiency.

FIG. 10 shows the addition of a plurality of ventilation openings 235 which allow air flow beneath modules 205 to increase efficiency and to decrease heat transfer from modules 205 and a structure (not shown).

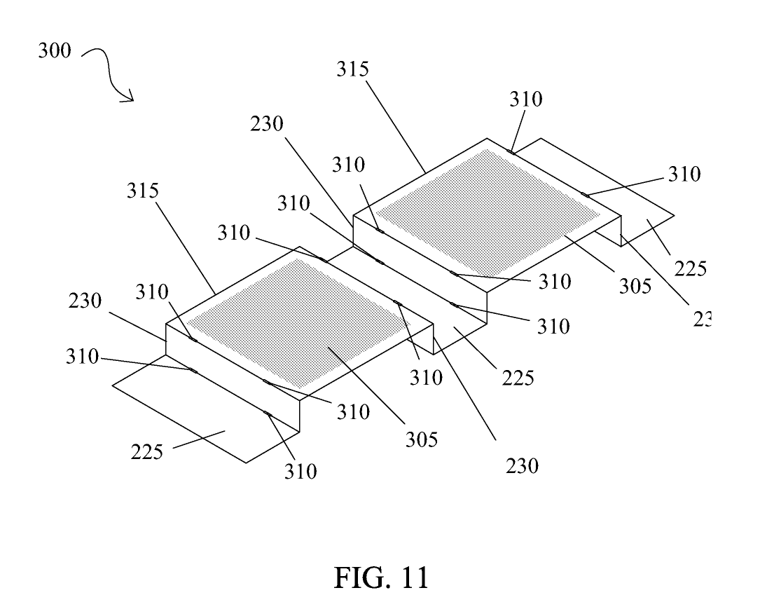

Now referring to FIG. 11, a configurable articulated photovoltaic assembly 300 comprises a plurality of photovoltaic modules 305 being attached to a support substrate 315 which as discussed above, can be made of glass or non glass materials including metal, polymers, composites, etc. that add to the structural integrity of the modules 305.

A plurality of base attachment plates 325 are attached to one end of modules 305. A plurality of risers 330 are hingedly attached to one end of module 305 and to an end of base attachment plates 325. This allows configurable articulated photovoltaic assembly 300 to fold generally flat when not in use and to be positioned with channels formed between modules 305.

The new invention is composed of a rigid panel is made from a number of different materials and components laminated together and integrated to form a lightweight rigid panel with very low deflection and torsion characteristics. One or more flexible thin polymer or metal films creating a module back sheets are laminated onto the panel to create the back laminated substrate assemble for a photovoltaic module. An a-Si, CIGS, or CdTe thin film photovoltaic material with optional polymer encapsulating films depending the solar material design and technology is laminated onto the back surface back sheet laminate.

The top of the photovoltaic carrier surface is covered and sealed by one or more layers of polymers that are solar transparent. Individual covering layers are chosen and layered in different combinations depending on the physical and chemical performance of each polymer. These covering materials can be moisture resistant, UV resistant polymer(s) and flexible, semi-flexible or rigid and any thickness depending on the performance characteristics and specifications of the PV module. Other transparent materials including glass and solid plastics can be integrated into the layers of polymers. The ability to use multi-layers of covering materials and indifferent thickness creates a number of new module design options.

The top surface covering material layer can be specified to have very strong UV resistance and good resistance to external environmental conditions and events. The inter-ply materials can have low UV resistance, but exhibit extremely strong hydrophobic characteristics and is protected from UV degradation by the top protective layer(s) that may have poor hydrophobic performance.

Other layers including thin a Fresnel lens in the panel helps to concentrate light to increase power performance. In addition to the thin film photovoltaic material, single or multi-crystalline silicon can be laminated onto the panel surface in-place of or with the thin film photovoltaic materials.

It is possible to use a one layer transparent polymer with a CIGS, A-Si or CdTe or solar active material in the module assembly and under this layer place another solar active material either thin film materials or crystalline silicon. The lower layer can absorb solar energy at different wavelengths and frequencies not absorbed by the higher placed transparent solar active polymer making effective use of a broader spectrum range of solar energy from the sun.

The invention makes use of rigid photovoltaic panels as a stand-alone PV module and can be installed using the many application methods described within this document. The invention also consists of these PV module panels linked or joined together using flexible joint materials, pivots or any type of hinged or swing joint that is suitable to join and link the panels to form a multi-unit panel PV module array. The multi-panel PV array can be folded up at the factory for easy shipment to the project where the module is unfolded and installed at the project using new application techniques designed specifically for this new module design or the different application technologies described within this document and applied to any building and construction surface(s). The same assembly and panel connection methods and technologies can be used with rigid silicon photovoltaic cells, including glass modules and glass hybrid modules and laminated polymer modules.

These new “fan-fold” modules can be applied to any sloped, horizontal or vertical surfaces. By connecting different types of non-solar active panels in-between, the solar active modules (panels) form a new transportable, foldable rack array system can be created on site without using standard rack array components. This new fan folded module array can be integrated onto any roof membrane systems and over metal roof surfaces, concrete and wall surfaces. These panels can be applied directly to any vertical, sloped or horizontal surface. By combining different interconnecting panels using the same flexible or hinged joint systems, different arrays can be created for different construction or building surfaces either as a single unit or in multi-unit configurations forming self-contained sloped (slanted) arrays or set up upon two equal sized non-solar panels to create an array raised off the application surface. With set module lengths, wiring is highly simplified and can be daisy chained together.

Although the instant invention has been described in relation to particular embodiments thereof, many other variations and modifications and other uses will become apparent to those skilled in the art.

1. A configurable articulated photovoltaic assembly comprises:
at least two photovoltaic module; and
a hinging means disposed between said at least two photovoltaic modules for allowing said at least two photovoltaic modules to fold flat.

2. The configurable articulated photovoltaic assembly according to claim 1 wherein said hinging means comprises at least one bidirectional hinge.

3. The configurable articulated photovoltaic assembly according to claim 1 wherein said hinging means comprises a fabric hinge.

4. The configurable articulated photovoltaic assembly according to claim 1 wherein said hinging means comprises a sliding extending hinge.

5. The configurable articulated photovoltaic assembly according to claim 1 further comprising a junction box electrically connected to each of said at least two photovoltaic modules.

6. The configurable articulated photovoltaic assembly according to claim 1 further comprising a support substrate wherein said photovoltaic module is mounted therein.

7. The configurable articulated photovoltaic assembly according to claim 1 wherein said support substrate is thermally insulative.

8. A configurable articulated photovoltaic assembly comprises:
a plurality of photovoltaic modules;
a hinging means disposed between each one of said plurality of photovoltaic modules for folding said plurality of photovoltaic modules; and
said hinging means being configured to allow each of said photovoltaic module to fold flat.

9. The configurable articulated photovoltaic assembly according to claim 8 wherein said hinging means being configured to position said plurality of photovoltaic modules at a selected orientation.

10. A configurable articulated photovoltaic assembly comprises:
at least one photovoltaic module;
an attachment plate attached to one end of said at least one photovoltaic module; and
a riser attached to an other end of said at least one photovoltaic module wherein said at least one photovoltaic module may be folded flat for storage and raised for use to orient said at least one photovoltaic module to a selected position.

11. The configurable articulated photovoltaic assembly according to claim 10 wherein said selected position forms a triangle.

12. The configurable articulated photovoltaic assembly according to claim 10 further comprising at least one ventilation opening disposed within said riser.

13. (canceled)

14. The configurable articulated photovoltaic assembly according to claim 10 wherein said selected position forms a channel between said at least two modules.
